(19) United States
(12) Patent Application Publication
(10) Pub. No.: US 2026/0255532 A1
(43) Pub. Date: Aug. 27, 2026

(54) METHOD OF SPLITTING A SEMICONDUCTOR SUBSTRATE AND COOLING PLATE APPARATUS

(71) Applicant: Infineon Technologies AG, Neubiberg (DE)

(72) Inventors: Tom Galle, Dresden (DE); Reyk Sikmanis, Dresden (DE)

(21) Appl. No.: 19/539,380

(22) Filed: Feb. 13, 2026

(30) Foreign Application Priority Data
Feb. 27, 2025 (DE) 102025107382.1

(51) Int. Cl. H05K 7/20; H10W 40/47

(52) U.S. Cl. CPC H05K 7/20254; H10W 40/47

(57) ABSTRACT

A method includes bringing a solid substrate composite in contact with a cooling surface of a cooling plate. The solid substrate composite includes a semiconductor substrate and an auxiliary layer formed on a first surface of the semiconductor substrate. The auxiliary layer and the semiconductor substrate have different coefficients of thermal expansion. A release layer is formed in the semiconductor substrate between the first surface and a second surface opposite the first surface. In a cooling period, the cooling plate is cooled and a gravity-independent clamping force is generated that clamps the solid substrate composite and the cooling plate to each other, such that the solid substrate composite splits along the release layer.

### TECHNICAL FIELD

The present disclosure relates to methods of splitting a semiconductor substrate and to cooling plate apparatuses adapted for splitting a semiconductor substrate.

### BACKGROUND

Thin crystalline semiconductor substrates, such as semiconductor wafers, can be cleaved from a crystalline boule by sawing or by cleaving along prepared release planes, wherein the release planes are formed by locally modifying the boule material by laser irradiation, ion implantation or other methods. Mechanical forces then cleave the crystalline boule along the release plane. In some methods, an auxiliary layer made of a material with a coefficient of thermal expansion that differs significantly from the coefficient of thermal expansion of the crystalline boule is firmly bonded to the crystalline boule. Cooling of the substrate composite, which includes the crystalline boule and the auxiliary layer, generates thermomechanical stresses and the crystalline boule splits along the release layer. There is a constant need to improve the yield of thin substrates obtained from crystalline boules by splitting processes in which a substrate composite is cooled to generate thermomechanical stresses.

### SUMMARY

An example of the present disclosure relates to a method of splitting a semiconductor substrate. The method includes bringing a solid substrate composite in contact with a cooling surface of a cooling plate. The solid substrate composite comprises a semiconductor substrate and an auxiliary layer formed on a first surface of the semiconductor substrate, wherein the auxiliary layer and the semiconductor substrate have different coefficients of thermal expansion. A release layer is formed in the semiconductor substrate between the first surface and a second surface opposite the first surface. In a cooling period, the cooling plate is cooled and a gravity-independent clamping force is generated that clamps the solid substrate composite and the cooling plate to each other, wherein the solid substrate composite splits along the release layer.

If the semiconductor substrate is comparatively thin, the cooling generates thermomechanical stresses that bend the solid substrate composite. The bending may result in that the semiconductor substrate sometimes cannot withstand the forces required to trigger the splitting process by cooling the solid substrate composite, with the result that the semiconductor substrate breaks outside the release layer or that the splitting is incomplete. By applying the gravity-independent clamping force, the cooling plate can mechanically support the solid substrate composite before and during the splitting process. The clamping force may suppress bending of the solid substrate composite and a resulting planar aligned release plane may result in a better controlled propagation of a crack surface that splits the semiconductor substrate. After splitting of the semiconductor substrate, the gravity-independent clamping force may stabilize thin substrates obtained by the splitting process. The probability that the semiconductor substrate is cleaved outside the release layer, the cleavage is incomplete or that the thin substrates obtained are damaged in the splitting apparatus can be reduced. The yield of the splitting process can be improved.

Another example of the present disclosure relates to a cooling plate apparatus. The cooling plate apparatus includes a cooling plate and a clamping force generation unit. The cooling plate has a cooling surface and is configured to cool a solid substrate composite, which is in direct contact with the cooling surface, to a temperature below -100 degree Celsius in a cooling period. The clamping force generation unit is configured to generate a gravity-independent clamping force between the cooling plate and the solid substrate composite, which is in direct contact with the cooling surface, in the cooling period.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1A to 1B illustrate a method of splitting a semiconductor substrate using a gravity-independent clamping force and a cooling plate in suspension configuration in accordance with an embodiment.

FIG. 2A to 2D illustrate a method of splitting a semiconductor substrate using a gravity-independent clamping force and a cooling plate in support configuration in accordance with an embodiment.

FIG. 3 illustrates a cooling plate employing vacuum chucking in suspension configuration in combination with a counter plate in support configuration in a cooling period of a solid substrate composite in accordance with an embodiment.

FIG. 4A to 4B illustrate phases of a method of splitting a semiconductor substrate using a cooling plate employing vacuum chucking and an auxiliary cooling plate in support configuration in accordance with an embodiment.

FIG. 5 is a schematic vertical cross-sectional view of a cooling plate apparatus including a cooling plate and configured to generate a gravity-independent clamping force in accordance with an embodiment.

FIG. 6 is a schematic vertical cross-sectional view of a cooling plate apparatus including a cooling plate with air ducts for vacuum chucking in accordance with an embodiment.

FIG. 7 is a schematic vertical cross-sectional view of a cooling plate apparatus including a porous cooling plate with microchannels for vacuum chucking in accordance with another embodiment.

FIG. 8 is a schematic vertical cross-sectional view of a cooling plate apparatus including a cooling plate with electrodes for electrostatic chucking in accordance with an embodiment directed to electrodes near a cooling surface.

FIG. 9 is a schematic vertical cross-sectional view of a cooling plate apparatus including a cooling plate with electrodes for electrostatic chucking in accordance with an embodiment directed to electrodes at a distance from a cooling surface.

FIG. 10 is a schematic vertical cross-sectional view of a cooling plate apparatus including a counter plate and a cooling plate with air ducts for vacuum chucking in accordance with an embodiment related to cooling plates in suspension configuration.

FIG. 11 is a schematic vertical cross-sectional view of a cooling plate apparatus including an auxiliary cooling plate and a cooling plate with air ducts for vacuum chucking in accordance with another embodiment related to cooling plates in suspension configuration.

### DETAILED DESCRIPTION

In the following detailed description, reference is made to the accompanying drawings, which form a part hereof and in which are shown by way of illustrations specific examples of methods and apparatuses for separating semiconductor substrates. It is to be understood that other examples may be utilized and structural or logical changes may be made without departing from the scope of the present disclosure. For example, features illustrated or described for one example can be used in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms "having", "containing", "including", "including" and the like are open, and the terms indicate the presence of stated structures, elements or features but do not preclude the presence of additional elements or features. The articles "a", "an" and "the" are intended to include the plural as well as the singular, unless the context clearly indicates otherwise.

Ranges given for physical dimensions include the boundary values. For example, a range for a parameter y from a to b reads as a ≤ y ≤ b. The same holds for ranges with one boundary value like “at most” and “at least”.

The terms "on" and “over” are not to be construed as meaning only "directly on" and “directly over”. Rather, if one element is positioned "on" or “over” another element (e.g., a layer is "on" or “over” another layer or "on" or “over” a substrate), a further component (e.g., a further layer) may be positioned between the two elements (e.g., a further layer may be positioned between a layer and a substrate if the layer is "on" or “over” said substrate).

An example of the present disclosure relates to a method of splitting a semiconductor substrate. The method includes bringing a solid substrate composite in contact with a cooling surface of a cooling plate. The solid substrate composite includes a semiconductor substrate and an auxiliary layer formed on a first surface of the semiconductor substrate, wherein the auxiliary layer and the semiconductor substrate have different coefficients of thermal expansion. A release layer is formed in the semiconductor substrate between the first surface and a second surface opposite the first surface. In a cooling period, the cooling plate is cooled and a gravity-independent clamping force is generated that clamps the solid substrate composite and the cooling plate to each other, wherein the solid substrate composite splits along the release layer.

The semiconductor substrate may be e.g. a wafer or an ingot. The shape of the semiconductor substrate may be a cylinder with an approximately planar first surface at one end of the cylinder and an approximately planar second surface at the other end. The first surface and the second surface may be parallel or at least approximately parallel to each other. The cylinder may be a right cylinder, e.g., a right circular cylinder with a circular base. In other examples, the base of the cylinder may be a circle with a notch or flat. The semiconductor substrate may be a so-called semiconductor puck, which is sometimes also referred to as a semiconductor boule. The semiconductor substrate may be a polycrystalline or single-crystalline semiconductor substrate (e.g. a single-crystalline puck).

The semiconductor may be an elementary semiconductor like silicon Si or germanium Ge or a compound semiconductor, e.g. a group IV compound semiconductor such as silicon carbide SiC, or a group III/V compound semiconductor such as gallium arsenide GaAs or gallium nitride GaN. In an example, the semiconductor substrate is a SiC wafer or a SiC puck with polished surfaces.

In the release layer, the mechanical strength of the semiconductor substrate is lower than outside the release layer. For example, a crystal lattice in the release layer 115 may have crystal lattice defects, for example two-dimensional crystal lattice defects.

The release layer can be formed by laser irradiation through the first surface and/or the second surface, wherein the laser radiation is focused at a predefined distance from the entrance surface. The focused laser radiation locally heats the crystal structure and locally modifies the crystal lattice. In modified regions, the crystal lattice is severely damaged, e.g. amorphized. In the modified regions of a compound semiconductor, the compound may be separated into the components. In addition, the heating may generate subcritical cracks in the semiconductor substrate, wherein the subcritical cracks originate at or near the modified regions and propagate along main crystal planes. Alternatively, the release layer may be formed by implanting ions through the first surface and/or the second surface, or by other forms of particle and/or electromagnetic radiation locally modifying the crystal lattice of the semiconductor substrate.

The coefficient of thermal extension (CTE) of the auxiliary layer can deviate considerably from the CTE of the semiconductor substrate. For example, the CTE of the auxiliary layer can be at least ten times, e.g. at least 30 times or at least 50 times greater than the CTE of the semiconductor substrate. In addition to the CTE difference, a linear progression of the CTE in the auxiliary layer over a wide temperature range can be advantageous. The auxiliary layer can have a comparatively high thermal conductivity.

In addition to the semiconductor substrate and the auxiliary layer, the solid substrate composite may include one or more additional layers, films, and/or foils. For example, a transport foil may be attached to the side of the auxiliary layer opposite the semiconductor substrate. Alternatively or in addition, an auxiliary foil may be attached to the second surface of the semiconductor substrate. Alternatively or in addition, a separation foil may be provided between the semiconductor substrate and the auxiliary layer. Each of the additional layers, films, and/or foils may be homogenous or may include two or more sub-layers of different composition. Each of the additional layers and/or films may be thinner than the auxiliary layer. The auxiliary layer may have a thermal conductivity of at least 0.1 W/(m*K).

The cooling plate may include two parallel plate portions and a coolant duct formed along an interface between the two plate portions. Each of the plate portions may include a main part formed from an elementary metal, e.g. copper Cu or aluminum Al, a metal compound or a metal alloy. The cooling plate can be in a support configuration, where the cooling surface is oriented against the direction of gravity (upwards), or in a suspension configuration, where the cooling surface is oriented in the direction of gravity (downwards).

The cooling surface may be approximately flat. The cooling surface may be completely flat with a residual roughness or may be flat with regular indentations, notches and/or grooves having lateral dimensions that are small, e.g. two orders of magnitude smaller than a horizontal dimension of the cooling surface in the plane of the cooling surface. The cooling surface can, for example, have openings to an air duct system that can be set under negative pressure.

Bringing the cooling plate into direct contact with the solid substrate composite may include placing the solid substrate composite on the cooling surface in case the cooling plate has a support configuration or lowering the cooling plate in direction of a solid substrate composite placed below the cooling surface until the cooling surface reaches the solid substrate composite and is in solid-state contact with the solid substrate composite.

The period during which the cooling plate is in direct solid-state contact with the solid substrate composite defines the cooling period, regardless of a temperature difference between the cooling plate and the solid substrate composite.

Cooling the cooling plate may include feeding a coolant into the coolant duct in response to a control signal received from a control unit. The coolant may be liquid at 20 degrees Celsius and may have a boiling point below -130 degree Celsius, e.g., below -135 degree Celsius or below -150 degree Celsius at standard atmospheric pressure. For example, the coolant may be or contain liquid nitrogen N₂. The cooling plate cools the solid substrate composite including the auxiliary layer during the cooling period. The coolant flow may start before the cooling period, i.e., before a direct solid-state contact is established between the cooling plate and the solid substate composite, simultaneously with the establishment of the solid-state contact, or after establishment of the solid-state contact. The coolant flow can end before the end of the cooling period, i.e., before the direct solid-state contact between the cooling plate and the solid substate composite is released, simultaneously with the release of the solid-state contact, or after the solid-state contact is released. During the cooling period, the coolant flow may be constant or may vary with time.

The comparatively high difference in CTE in combination with the strong bond between the semiconductor substrate and the auxiliary layer effects a high thermomechanical stress in the auxiliary layer and the semiconductor substrate. In the semiconductor substrate, the subcritical cracks previously formed in the release layer can spread further along the main crystal planes. Depending on the crystal lattice of the semiconductor substrate and the orientation of main crystal planes with respect to the first surface and the second surface, the crystal may crack between lattice defects in different crystal planes. Regardless of the lattice type and lattice orientation, a continuous crack surface may develop, which finally separates the semiconductor substrate completely into the first portion and the second portion in most cases.

If a total thickness of the semiconductor substrate is less than a critical thickness, then the high mechanical forces effective between the auxiliary layer and the semiconductor substrate result in a significant bending of the solid substrate composite. Then the mechanical strength of the semiconductor substrate may be insufficient to survive the cooling cycle and the semiconductor substrate may break outside the release layer before a continuous crack surface completely separates the semiconductor substrate into the first portion and the second portion. In addition, a propagation of the continuous crack surface may come to a standstill before the first portion is completely separated from the second portion. For example, the continuous crack surface may leave out a central part of the release layer. For a single-crystalline SiC puck or SiC wafer, the critical thickness may be 3 mm or less, e.g. 2 mm or 1.5 mm.

The gravity-independent clamping force may be a surface force resulting from a pressure difference or an electrostatic force, by way of example. Depending on the orientation of the cooling surface, the gravity-independent clamping force may add to a weight force exerted by the solid substrate composite, the cooling plate, a substrate holder, and/or a counter plate, may work in the opposite direction of the weight force, or may act transversely to the weight force. The cooling period begins when both the cooling plate is in contact with the solid substrate composite and the cooling plate is actively cooled, e.g., by supplying a coolant into coolant ducts formed in the cooling plate. The cooling period ends when at least one of the two conditions is no longer fulfilled, e.g., as soon as the cooling plate and the solid substrate composite are detached from each other, or the active cooling of the cooling plate is ended. The gravity-independent clamping force may be activated before the cooling period, at the start of the cooling period or after the start of the cooling period. The gravity-independent clamping force may be deactivated before the end of the cooling period, with end of the cooling period or after the end of the cooling period.

By applying the gravity-independent clamping force, the cooling plate can mechanically support the solid substrate composite before and during the splitting process. In addition, the clamping force may reduce or suppress bending of the solid substrate composite so that the release layer is aligned along a flat plane. The propagation of the crack that splits the semiconductor substrate can be better controlled and the probability that the crack spares a horizontal center portion of the release layer can be reduced. During and shortly after the splitting of the semiconductor substrate, the gravity-independent clamping force may stabilize the thin substrates against breakage when the thin substrates relax. After relaxation, the gravity-independent clamping force may hold the thin substrates in place until a handler picks the thin substrates. The probability that the semiconductor substrate is incompletely cleaved or that the resulting thin substrates are damaged in the splitting apparatus can be reduced. The yield of the splitting process can be improved.

According to an example, the method may include applying the auxiliary layer to the semiconductor substrate to form the solid substrate composite, wherein the auxiliary layer may include a material exhibiting a glass transition at a glass transition temperature, and wherein cooling the cooling plate may cool the auxiliary layer to a temperature below the glass transition temperature.

Forming the auxiliary layer on the first surface of the semiconductor substrate may include a bonding process to allow for a firm bond to form that is resilient against the following cooling process. For example, before applying the auxiliary layer, an application surface of the auxiliary layer and/or the first surface of the semiconductor substrate may undergo chemical and/or physical surface treatment (for example with a plasma). The surface treatment may remove impurities, may planarize the surface, and/or may activate/deactivate surface bonds.

The auxiliary layer may include or consist of any material that undergoes a glass transition, such as a polymer, another organic glass, or an inorganic glass. The auxiliary layer may include or consist of a dielectric material. The glass transition may significantly change mechanical properties such as viscosity and/or elasticity of the material passing through the glass transition. The glass transition may cause the auxiliary layer to become harder and/or more brittle, so that the auxiliary layer can exert significant higher mechanical stress on the semiconductor substrate after the glass transition than before the glass transition. The CTE of the auxiliary layer may be at least 250 ppm/°C (250 × 10⁻⁶K⁻¹, 250E-6 1/K), for example at least 300 ppm/°C (300 × 10⁻⁶K⁻¹, 300E-6 1/K).

According to an example, the method may include forming the release layer in the semiconductor substrate, wherein forming the release layer may include locally modifying a composition and/or a structure of the semiconductor substrate.

The release layer can be formed by laser irradiation through the first surface and/or the second surface, wherein the laser radiation is focused in a predefined distance from the entrance surface. The focused laser radiation may locally heat the crystal structure and locally modify the crystalline lattice. In modified regions, the crystal lattice is severely damaged, e.g. amorphized. In the modified regions of a compound semiconductor, the compound may be separated into the components. In addition, the heating may generate subcritical cracks in the semiconductor substrate, wherein the subcritical cracks originate at or near the modified regions and propagate along main crystal planes of the semiconductor crystal of the semiconductor substrate. The subcritical cracks are sufficiently short such that the majority of the subcritical cracks do not merge with each other, and no continuous split-off plane is formed across the complete cross-section of the semiconductor substrate. A maximum lateral extension of a subcritical crack may be smaller than a lateral distance between neighboring modified regions. Alternatively, the release layer may be formed by implanting ions through the first surface and/or the second surface, or by other forms of particle and/or electromagnetic radiation locally modifying the crystal lattice of the semiconductor substrate.

According to an example, the cooling plate may be brought into direct contact with the auxiliary layer or the semiconductor substrate. A solid-state contact between the cooling plate and the auxiliary layer or the semiconductor substrate may provide high thermal conductivity between the cooling plate and the semiconductor substrate and a short process time.

The gravity-independent clamping force may be controlled such that the at least 90%, for example, 100% of the area of a contact surface of the solid substrate composite oriented to the cooling plate is in direct contact with the cooling surface of the cooling plate.

According to an example, the method may include bringing the solid substrate composite in contact with a working surface of a counter plate to position the solid substrate composite between the working surface and the cooling surface for the cooling period.

The solid substrate composite may be brought into contact with the counter plate before the cooling period, with begin of the cooling period or after the begin of the cooling period. The solid substrate composite may be removed from the counter plate, or the counter plate may be detached from the solid substrate composite before the end of the cooling period, with end of the cooling period or after the end of the cooling period.

For example, the cooling plate is in direct solid-state contact with the semiconductor substrate or with an additional layer, film or foil on the side of the semiconductor substrate opposite the auxiliary layer, and the counter plate is in direct contact with the auxiliary layer or with another additional layer, film or foil between the auxiliary layer and the counter plate. According to another example, the cooling plate is in direct solid-state contact with the auxiliary layer or with an additional layer, film or foil on the side of the auxiliary layer opposite the semiconductor substrate, and the counter plate is in direct contact with the semiconductor substrate or with another additional layer, film or foil between the semiconductor substrate and the counter plate.

According to an example, the counter plate may be configured as auxiliary cooling plate, the working surface of the counter plate may be configured as auxiliary cooling surface, and the counter plate is cooled in the cooling period.

Configured as auxiliary cooling plate, the counter plate may be actively cooled by supplying a coolant into coolant ducts formed in the counter plate. Active cooling of the counter plate may begin before the cooling period, with begin of the cooling period or after the begin of the cooling period. Active cooling of the counter plate may be ended before the end of the cooling period, with end of the cooling period or after the end of the cooling period. The counter plate may include two parallel plate portions and a coolant duct formed along an interface between two plate portions. Each of the plate portions may include a main part formed from an elementary metal, e.g. copper Cu or aluminum Al, a metal compound or a metal alloy. The counter plate is in a suspension configuration when the cooling plate has a support configuration. The counter plate is in a support configuration when the cooling plate is in a suspension configuration.

In the latter case, bringing the counter plate into direct contact with the solid substrate composite may include placing the solid substrate composite on the auxiliary cooling surface of the counter plate and lowering the cooling plate in direction of the solid substrate composite until the cooling surface is in solid-state contact with the solid substrate composite and the solid substrate composite is clamped between the cooling surface of the cooling plate and the auxiliary cooling surface of the counter plate.

The counter plate can be in direct solid-state contact with the solid substrate composite during the complete cooling period or at least for a part of the cooling period. Cooling the auxiliary cooling plate may include feeding a coolant, e.g. liquid nitrogen N₂ into the coolant duct in response to a control signal received from a control unit. The coolant flow may start before the cooling period, simultaneously with the cooling period, or after the begin of the cooling period. The coolant flow can end before the end of the cooling period, simultaneously with the cooling period, or after the cooling period. The coolant flow through the coolant duct of the auxiliary cooling plate may be constant or may vary with time.

According to an example, the clamping force may include a surface force resulting from a pressure difference, wherein the pressure difference is generated by drawing air from the cooling surface. If the solid substrate composite is close enough to the cooling surface, the cooling plate draws the solid substrate composite onto the cooling surface. The solid substrate composite closes the openings of the air ducts, and a pressure difference builds up between the outside of the cooling plate and the air duct system in the cooling plate. In addition to the cooling functionality, the cooling plate may be configured as vacuum chuck.

According to another example, the clamping force includes an electrical force, wherein the electrical force is generated by generating an electrical field effective between the solid substrate composite and the cooling plate.

In addition to the cooling functionality, the cooling plate 210 may be configured as electrostatic chuck (E-Chuck, ESC) that absorbs and fixes (chucks) a workpiece by using an electrical force that causes objects to attract each other with static electricity. The cooling plate may be configured as monopolar chuck, or as bipolar chuck, by way of example.

According to an embodiment, cooling the cooling plate may include feeding a liquid coolant into a coolant duct formed in the cooling plate, wherein the liquid coolant vaporizes in the coolant duct, and wherein the vaporized coolant is discharged from the coolant duct.

According to an embodiment, a boiling temperature of the coolant may be below -130 degrees Celsius, for example below -135 degree Celsius or below -150 degree Celsius.

Another example of the present disclosure relates to a cooling plate apparatus. The cooling plate apparatus may include a cooling plate having a cooling surface and a clamping force generation unit. The cooling plate may be configured to cool a solid substrate composite, which is in direct contact with the cooling surface, to a temperature below -100 degree Celsius in a cooling period. The clamping force generation unit may be configured to generate a gravity-independent clamping force between the cooling plate and the solid substrate composite, which is in direct contact with the cooling surface in the cooling period. The gravity-independent clamping force may be a surface force acting normally over a contact area between the cooling surface and the solid substrate composite.

According to an example, the cooling plate may include a coolant feeding duct configured to receive a liquid coolant, a coolant duct suitable for letting vaporize the liquid coolant; and a coolant discharge duct configured to discharge the vaporized coolant from the coolant duct.

According to an example, the liquid coolant may contain liquid nitrogen. The cooling plate may be configured to cool a solid substrate composite, which is in direct contact with the cooling surface, to a temperature below -130 degree Celsius, e.g., below -135 degree Celsius or below -150 degree Celsius.

According to an example, the cooling plate may further include a phase separator configured to separate a vaporized coolant portion from a liquid coolant portion to pass only liquid coolant portion to the coolant feeding duct. For example, the phase separator may separate gaseous nitrogen N₂ from liquid nitrogen N₂ to feed only liquid nitrogen N₂ into the coolant feeding duct. Alternatively or in addition, the cooling plate may further include a condenser unit configured to condense the vaporized coolant received from the coolant discharge duct, and to pass the condensed coolant back to a coolant tank or the phase separator. For example, the condenser unit may condense gaseous nitrogen N₂ to liquid nitrogen N₂ and passes the liquid nitrogen N₂ back to a liquid nitrogen tank or the phase separator.

According to an example, the cooling plate may include a first plate portion forming the cooling surface, wherein a thermal conductivity of a main part of the first plate portion is greater than 10 W/(m*K).

The first plate portion may form a right cylinder with the cooling surface forming the bottom base and an essentially flat backside surface opposite the cooling surface forming the top base. The backside surface may be at least partially exposed and components of devices for cooling the first plate portion, for generating the gravity-independent clamping force and/or for positioning the cooling plate may be attached to and/or formed on the backside surface. Alternatively, the cooling plate may further include a second plate portion in contact with the backside surface of the first plate portion. The second plate portion may be another right cylinder with the same or approximately the same diameter as the first plate portion. Components of devices for cooling the first plate portion and/or for generating the gravity-independent clamping force may be provided and/or formed along the interface between the first plate portion and the second plate portion. The main part of the first plate portion forms the body of the first plate portion. In addition to the main part, the first plate portion may include coating(s) and/or fittings. The thermal conductivity of the main part dominates the thermal conductivity of the first plate portion. For a main part formed from non-porous material, the thermal conductive may be greater than 100 W/(m*K), greater than 200 W/(m*K), or greater than 500 W/(m*K) at the standard temperature of 20 degree Celsius. The main part of the first plate portion may contain at least one of aluminum, iron, and copper as a main constituent.

According to an example, the clamping force generation unit may include air ducts formed in the cooling plate, wherein openings of the air ducts are formed in the cooling surface. The clamping force generation unit may generate a pressure difference between the surroundings of the solid substrate composite and the air ducts, and the pressure difference generates a surface force pressing the solid substrate composite against the cooling surface. The resulting pressure may be uniform across a complete contact area between the cooling surface and the solid substrate composite.

The cooling plate may be made of a non-porous material, wherein the air ducts can be defined by a mold and/or formed by metalworking such as milling, drilling, grinding, and/or by etching.

According to another example, the cooling plate may include a porous material containing pores that form the air ducts. For example, at least a central section of the first plate portion or the complete main part of the first plate potion may have a porosity of at least 20% or at least 35%. The porous main part of the first plate portion, or the porous main parts of the first plate portion and the second plate portion may include an inorganic material and a cured binder. The inorganic material may include a metal like elemental aluminum Al, elemental iron Fe or elemental copper Cu, or a non-metallic material like silicon carbide SiC or alumina Al₂O₃. The thermal conductivity of a porous main part of the first plate portion may be greater than 15 W/(m*K), greater than 20 W/(m*K) or greater than 30 W/(m*K).

According to an example, a vacuum pump may be configured to draw in air from the air ducts. For cooling plates based on non-porous materials, the vacuum pump may be connected to the air ducts. For example, a collector duct and an extraction duct may be formed in the cooling plate, wherein the collector duct connects the air ducts with the extraction duct. The vacuum pump may be operatively connected to the extraction duct. For cooling plates based on porous materials, the vacuum pump may draw air from the backside of the cooling plate opposite the cooling surface.

According to an example, the clamping force generation unit may include at least one electrode configured to generate an electrical field with field lines crossing the cooling surface. The electric field may generate an electrostatic force pressing a solid substrate composite against the cooling surface. The clamping force generation unit may include one single electrode in a monopolar configuration, two electrodes in a bipolar configuration, or more than two electrodes. Each electrode may be a plate, layer or foil that is aligned parallel to the cooling surface. A dielectric embedding may surround each electrode. The field lines may cross the cooling surface approximately or perfectly orthogonally.

According to an example, the clamping force generation unit may include at least one electrode configured to generate an electrical field with field lines crossing the cooling surface, and the coolant duct may be formed along a plane parallel to the cooling surface between the at least one electrode and the cooling surface.

According to an example, the cooling plate apparatus may further include a voltage source configured to supply a voltage to the at least one electrode. The voltage source may include a DC voltage source and/or an AC voltage source supplying a clamp voltage of at least 100V. In a bipolar configuration, the clamp voltage may be applied between two electrodes integrated in the same cooling plate.

According to an example, the cooling plate apparatus may further include a counter plate having a working surface opposite the cooling surface of the cooling plate, wherein the cooling plate and the counter plate are configured such that the solid substrate composite can be placed between the cooling surface and the working surface.

At least one of the cooling plate and the counter plate may be moveable along a displacement axis orthogonal to the cooling surface. The displacement axis may be parallel to the direction of gravity. The cooling plate and the counter plate may be configured to clamp the solid substrate composite between the cooling surface and the working surface before and/or during the cooling period.

According to an example, the counter plate may be configured as auxiliary cooling plate configured to be cooled before and/or in the cooling period. The auxiliary cooling plate may contribute to a faster and/or more uniform cooling of the solid substrate composite.

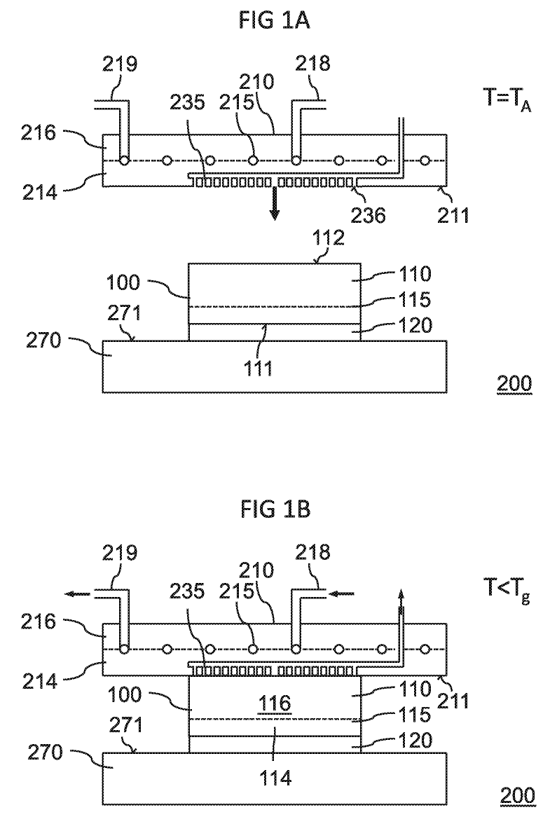

FIG. 1A to FIG. 1B show successive phases of a method of splitting a semiconductor substrate 110 using a cooling plate apparatus 200.

FIG. 1A illustrates a cooling plate apparatus 200 that includes a cooling plate 210 in suspension configuration and a counter plate 270 in support configuration.

The cooling plate 210 includes a non-porous first plate portion 214 with the cooling surface 211 and a non-porous second plate portion 216. The first plate portion 214 and the second plate portion 216 have the same lateral dimensions and are in direct contact with each other along a planar interface. Each of the plate portions 214, 216 includes a main part. A thermal conductivity of the main part of at least the first plate portion 214 may be greater than 50 W/(m*K), for example greater than 100 W/(m*K) at 20 degrees Celsius. The main part of the first plate portion 214 may be formed from copper Cu, a copper alloy, iron, an iron alloy, aluminum or an aluminum alloy. The cooling plate 210 is heavier than 1kg, e.g., heavier than 5kg or 10kg.

The cooling surface 211 is directed downwards and aligned along a plane orthogonal to the force of gravity. The cooling surface 211 and a further part of the surface of the first plate portion 214 may be covered with diamond-like carbon DLC. A coolant duct 215 is formed along the interface between the plate portions 214, 216. The coolant duct 215 may form a flat, horizontal spiral duct connecting a vertical coolant feeding duct 218 and a vertical coolant discharge duct 219. The vertical coolant feeding duct 218 and the vertical coolant discharge duct 219 pass through the second plate portion 216. One or more column-like support structures (not illustrated) support and stabilize the cooling plate 210 in a process chamber.

In the illustrated example, the cooling plate 210 is based on a non-porous material and include an air duct system. The air duct system includes air ducts 235 with openings 236 formed in the cooling surface 211 of the cooling plate 210. A cross-sectional area of the openings 236 may be in a range from 0.5 mm to 6 mm, e.g. from 1 mm to 5 mm. A mean distance between neighboring openings 236 may be in a range from 0.5 cm to 5 cm, e.g., 1 cm to 3 cm.

The counter plate 270 is configured as substrate holder. A portion of the counter plate 270 with low thermal conductivity may form the working surface 271. The working surface 271 can be planar or may include a recess matching the horizontal dimensions of the solid substrate composite 100. The working surface 271 is oriented upwards.

A handler unit may place a solid substrate composite 100 on the working surface 271 when the counter plate 270 and the cooling plate 210 are fixed at a loading distance to each other which is greater than the vertical extension of the solid substrate composite 100.

The solid substrate composite 100 includes a semiconductor substrate 110 and an auxiliary layer 120 formed on a first surface 111 of the semiconductor substrate 110. The auxiliary layer 120 and the semiconductor substrate 110 have different coefficients of thermal expansion. A release layer 115 is formed in the semiconductor substrate 110 between the first surface 111 and a second surface 112 opposite the first surface 111 at a constant distance from the first surface 111. In the release layer 115, the mechanical strength of the semiconductor substrate 110 is lower than outside the release layer 115. For example, a crystal lattice in the release layer 115 may show two-dimensional crystal lattice defects.

FIG. 1A shows the cooling plate apparatus 200 in a loading configuration, wherein a distance between the cooling surface 211 of the cooling plate 210 and the working surface 271 of the counter plate 270 is sufficiently large to allow the solid substrate composite 100 to be placed on the working surface 271.

In the illustrated example, the solid substrate composite 100 is placed with the semiconductor substrate 110 oriented to the cooling surface 211. According to another example (not illustrated), the solid substrate composite 100 is placed with the semiconductor substrate 110 oriented to the working surface 271. The placement takes place at an ambient temperature TA of about 20° Celsius.

After placement of the solid substrate composite 100 on the working surface 271, the cooling plate 210 is lowered and/or the counter plate 270 is raised to bring the solid substrate composite 100 in contact with the cooling surface 211 of the cooling plate 210. Lowering of the cooling plate and/or raising the counter plate 270 can be stopped at a predefined distance between the solid substrate composite 100 and the cooling surface 211 and/or when the respective movement encounters a predefined resistance.

Air is drawn from the air duct system in the cooling plate 210, so that a pressure difference between the outside of the air duct system and the inside of the air duct system generates a surface force that presses the solid substrate composite 100 against the cooling plate 210 and counteracts a bending of the solid substrate composite 100.

FIG. 1B shows the solid substrate composite 100 clamped to the cooling surface 211 of the cooling plate 210. In the example shown, the cooling plate apparatus 200 is controlled such that the counter plate 270 remains in direct contact with the solid substrate composite 100 after the solid substrate composite 100 is clamped to the cooling plate 210. According to another example (not shown), the cooling plate apparatus 200 is controlled such that the counter plate 270 and the solid substrate composite 100 move away from each other after the solid substrate composite 100 has been clamped to the cooling plate 210. According to a further example (not shown), the cooling plate apparatus 200 is provided without counter plate 270 and the handler unit holds the solid substrate composite 100 at least until the solid substrate composite 100 clamps on the cooling plate 210.

A coolant is fed through the coolant feeding duct 218 to cool the cooling plate 210 and the solid substrate composite 100 down to below a glass transition temperature of the material of the auxiliary layer 120. The comparatively high difference in CTE in combination with the strong bond between the semiconductor substrate 110 and the auxiliary layer 120 creates high thermomechanical stresses in the auxiliary layer 120 and the semiconductor substrate 110. The subcritical cracks previously created during formation of the release layer 115 in the semiconductor substrate 110 can spread and propagate along main crystal planes. In the absence of bending of the solid substrate composite 100, a continuous crack surface can develop across the entire cross-section of the semiconductor substrate 110. A first substrate portion 114 of the semiconductor substrate 100 at a first side of the release layer 115 reliably cleaves from a second substrate portion 116 at the opposite side of the release layer 115. The cleaving may take place at a temperature lower than a glass transition temperature Tg of the auxiliary layer 120.

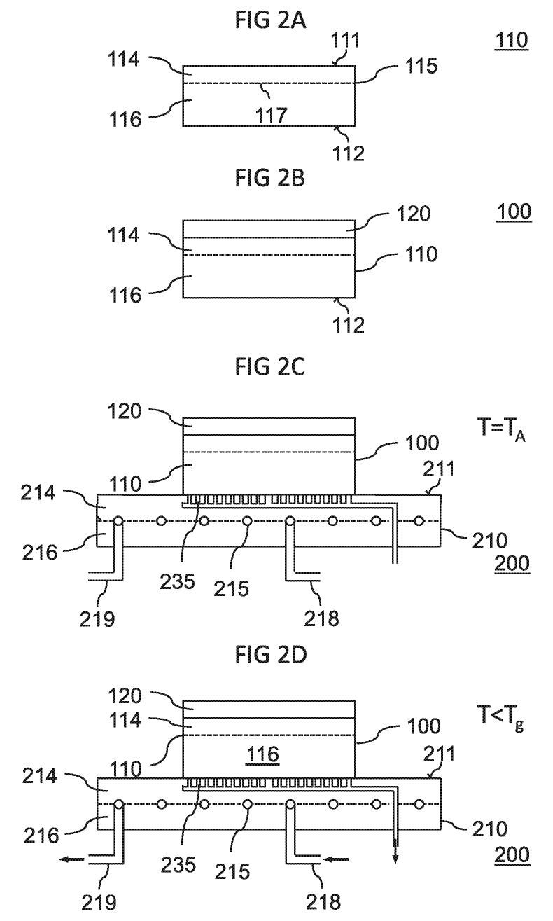

FIG. 2A to FIG. 2D show successive phases of a method of splitting a semiconductor substrate 110. A release layer 115 is formed in the semiconductor substrate 110 by laser irradiation.

FIG. 2A shows a semiconductor substrate 110 of single-crystalline silicon carbide SiC, e.g. silicon carbide of the 4H polytype. The semiconductor substrate 110 has the form of a cylinder with an approximately planar first surface 111 at one end of the cylinder and an approximately planar second surface 112 at the opposite end. The first surface 111 and the second surface 112 are oriented approximately parallel, e.g., parallel, to each other. The base of the cylinder is a complete circle or a circle with a notch or flat. For example, the semiconductor substrate 110 is a wafer or puck, for example a SiC wafer or a SiC puck.

The laser radiation enters the semiconductor substrate 110 through the first surface 111 and is focused at a predefined distance from the first surface 111. The focused laser radiation locally heats a focal point region in the semiconductor substrate 110 around the focal point, wherein in the focal point region the silicon carbide crystal decomposes. The decomposition products in the focal point region form a modified region 117 containing amorphous silicon and amorphous carbon. The high-temperature decomposition exerts high pressure on the portion of the silicon carbide crystal surrounding the focal point region. The pressure creates subcritical cracks in the part surrounding the modified region 117. The laser radiation is controlled so that a plurality of modified regions 117 are formed adjacent to each other and at the same distance from the first surface 111. The modified regions 117 and the sub-critical cracks originating at or adjacent to the modified regions 117 form the release layer 115.

The release layer 115 defines a first substrate portion 114 substantially between the first surface 111 and the release layer 115 and a second substrate portion 116 substantially between the release layer 115 and the second surface 112. Each of the first substrate portion 114 and the second substrate portion 116 includes portions of the release layer 115. The first substrate portion 114 and the second substrate portion 116 essentially complement each other to form the semiconductor substrate 110.

An auxiliary layer 120 is placed directly on the first surface 111. A bonding process provides a strong mechanical connection between the auxiliary layer 120 and the semiconductor substrate 110. The bonding process may involve pressing the auxiliary layer 120 and the semiconductor substrate 110 against each other, a heating treatment, or a combination of both.

FIG. 2B shows the auxiliary layer 120 bonded onto the first surface 111 of the semiconductor substrate 110. The bonding process may result in the creation of chemical bonds between the semiconductor substrate 110 and the auxiliary layer 120. The auxiliary layer 120 is based on PDMS containing a filler for high thermal conductivity. The CTE of the auxiliary layer 120 is at least 30 times or 50 times higher than the CTE of the semiconductor substrate 110. The auxiliary layer 120 and the semiconductor substrate 110 form a solid substrate composite 100.

The solid substrate composite 100 is placed in a cooling plate apparatus 200. According to FIG. 2C, the cooling plate apparatus 200 includes a cooling plate 210 in support configuration with the cooling surface 211 oriented upwards. The solid substrate composite 100 is placed directly on a cooling surface 211. Apart from the orientation of the cooling surface 211, the cooling plate 210 has the configuration of the cooling plate 210 in FIG. 1A.

The solid substrate composite 100 is placed with the second surface 112 of the semiconductor portion 110 oriented to the cooling surface 211. The placement may take place at an ambient temperature TA of about 20° Celsius or less. Then the solid substrate composite 100 may be clamped on the cooling surface 211, wherein a potentially bending of the solid substrate composite 100 is flattened.

Before or after placement of the solid substrate composite 100 in the cooling plate apparatus 200, liquid nitrogen N₂ or another suitable coolant is fed through the coolant feeding duct 218 into the coolant duct 215. The liquid nitrogen N₂ cools the cooling plate 210 and the solid substrate composite 110 with the auxiliary layer 120 and the semiconductor substrate 110. Gaseous N₂ leaves the coolant duct 215 through the coolant discharge duct 219. In the illustrated example, the coolant feeding duct 218 is placed closer to the horizontal center of the cooling plate 210 and the coolant discharge duct 219 is placed closer to the periphery of the cooling plate 210. Other examples may provide the coolant discharge duct 219 next to the horizontal center of the cooling plate 210 and the coolant feeding duct 218 closer to the periphery of the cooling plate 210, both the coolant feeding duct 218 and the coolant discharge duct 219 next to the horizontal center, or both the coolant feeding duct 218 and the coolant discharge duct 219 closer to the periphery of the cooling plate 210.

FIG. 2D shows the cooling plate 210 cooled by the continuous inflow of liquid nitrogen N₂. The resulting thermomechanical stresses cause the first substrate portion 114 to separate from the second substrate portion 116. The handler unit may lift the composite including the first substrate portion 114 and the auxiliary layer 120 from the first substrate portion 116.

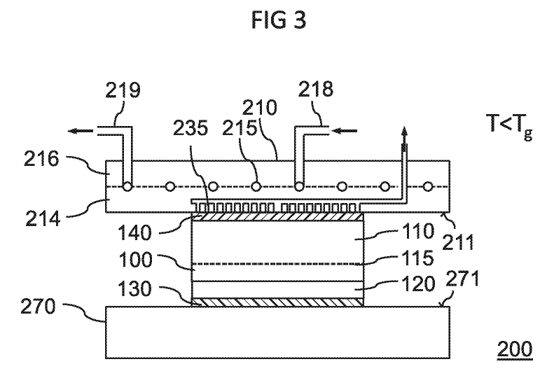

In FIG. 3, the solid substrate composite 100 includes a first additional layer, film or foil 130 formed on a surface of the auxiliary layer 120 opposite the semiconductor substrate 110. The first additional layer, film or foil 130 may be homogenous or may include two or more sublayers, wherein at least two of the sublayers have different material configurations, e.g., different compositions. The counter plate 270 and the first additional layer, film or foil 130 form a solid-state contact. The first additional layer, film or foil 130 may be or include a dicing tape.

In addition, the solid substrate composite 100 includes a second additional layer, film or foil 140 formed on the second surface 112 of the semiconductor substrate 110. The second additional layer, film or foil 140 may be homogenous or may include two or more sublayers, wherein at least two of the sublayers have different material configurations, e.g., different compositions. The thermal conductivity of the second additional layer, film or foil 140 is in the same order of magnitude as the thermal conductivity of the semiconductor substrate 110 or higher. The cooling plate 210 and the second additional layer, film or foil 140 form a solid-state contact. The second additional layer, film or foil 140 may be or include a protective tape.

In other examples, the solid substrate composite 100 includes only one of the first additional layer, film or foil 130 and the second additional layer, film or foil 140.

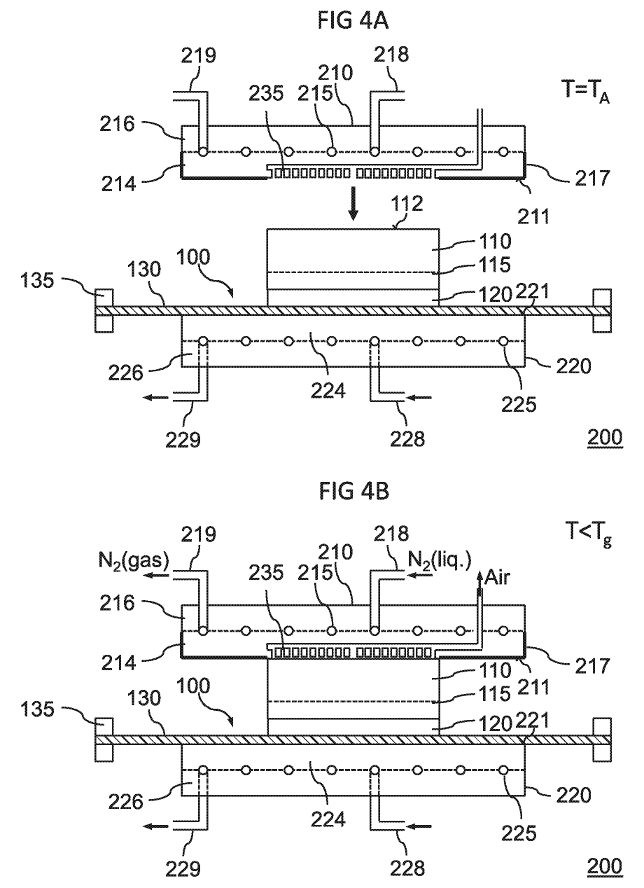

FIG. 4A shows a cooling plate apparatus 200 that includes a cooling plate 210 in suspension configuration and a counter plate configured as auxiliary cooling plate 220 in support configuration. The cooling plate 210 may have any of the configurations described above. In addition, a coating 217, e.g., a DLC coating may cover the cooling surface 211 and the outer surface of the first plate portion 214. The auxiliary cooling plate 220 may have a similar configuration as the cooling plate 210.

The auxiliary cooling plate 220 includes a first auxiliary plate portion 224 providing an auxiliary cooling surface 221 and a second auxiliary plate portion 226, wherein the first auxiliary plate portion 224 and the second auxiliary plate portion 226 have the same lateral dimensions and are in direct contact with each other along a planar interface. Each of the plate portions 224, 226 includes a main part formed from copper Cu or a copper alloy. The auxiliary cooling surface 221 is directed upwards and aligned in a plane orthogonal to the force of gravity. An auxiliary coolant duct 225 of the auxiliary cooling plate 220 is formed along the interface between the plate portions 224, 226. The auxiliary coolant duct 225 may form a flat, horizontal spiral duct connecting a vertical auxiliary coolant feeding duct 228 and a vertical auxiliary coolant discharge duct 229. The vertical auxiliary coolant feeding duct 228 and the vertical auxiliary coolant discharge duct 229 pass through the second auxiliary plate portion 226. One or more column-like support structures (not illustrated) carry and stabilize the auxiliary cooling plate 220 in a process chamber. The illustrated example of an auxiliary cooling plate does not contain air ducts with openings in the auxiliary cooling surface 221.

The solid substrate composite 100 includes a first additional layer, film or foil 130 configured as dicing tape stretched in a polygonal or round frame 135. A handler unit may use the frame 135 to load the cooling plate apparatus 200 with the solid substrate composite 100, wherein the handler unit places the frame 135 in such a way that the first additional layer, film or foil 130 rests on the auxiliary cooling plate 220 as illustrated in FIG. 4A.

The cooling plate 210 moves downwards and/or the auxiliary cooling plate 220 upwards and the cooling plate 210 clamps the solid substrate composite 100 by drawing air from the air duct system such that a pressure difference between outside the cooling plate 210 and the air ducts 235 generates a surface force that clamps the solid substrate composite 100 to the cooling surface 211 for a working configuration illustrated in FIG. 4B.

The cooling plate 210 is in direct solid-state contact with the semiconductor substrate 110. The auxiliary cooling plate 220 is in direct solid-state contact with the first additional layer, film or foil 130.

In the cooling period, a coolant, e.g. liquid nitrogen N₂, is fed into the coolant ducts 215, 225 in response to a control signal received from a control unit. The coolant flow may start before the cooling period, simultaneously with the cooling period, or after the begin of the cooling period. The coolant flow can end before the end of the cooling period, simultaneously with the cooling period, or after the cooling period. The coolant flow through the coolant ducts 215, 225 may be constant or may vary with time. The pressure difference between the outside of the cooling plate 210 and the air ducts 235 generates a surface force clamping the solid substrate composite 100 to the cooling surface 211 and suppressing or reducing a potential bending of the solid substrate composite 100.

FIG. 5 shows a cooling plate apparatus 200 that includes a cooling plate 210 and a clamping force generation unit 230. The cooling plate 210 has a cooling surface 211 and is configured to cool a solid substrate composite 100, which is in direct contact with the cooling surface 211, to a temperature below -100 degree Celsius, for example below -130 degree Celsius, below -135 degree Celsius or below -150 degree Celsius, for a cooling period. The clamping force generation unit 230 is configured to generate a gravity-independent clamping force between the cooling plate 210 and the solid substrate composite 100, which is in direct contact with the cooling surface 211 in the cooling period.

The cooling plate 210 includes a coolant feeding duct 218 that receives a liquid coolant, a coolant duct 215 suitable for letting vaporize the liquid coolant; and a coolant discharge duct 219 configured to discharge the vaporized coolant from the coolant duct 215. The coolant duct may be formed along an interface between a first plate portion 214 and a second plate portion 216 of the cooling plate 210 as described above. The coolant duct 215 is suitable for receiving and conducting a liquid coolant and for draining the vaporized coolant.

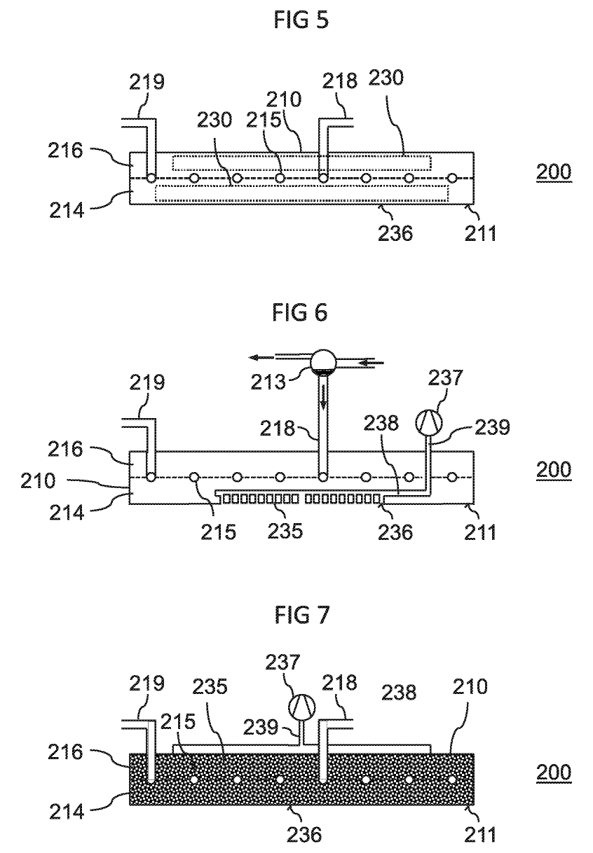

FIG. 6 shows a cooling plate apparatus 200 with a clamping force generation unit including an air duct system formed in the cooling plate 210. The air duct system includes air ducts 235 with openings 236 in the cooling surface 211, an extraction duct 239 and a collector duct 238 connecting the air ducts 235 with the extraction duct 239. A vacuum pump is operatively connected to the extraction duct 239. During operation, the vacuum pump 237 draws in air from the surroundings of the cooling surface 211. When a solid substrate composite 100 is sufficiently close to the cooling surface 211, the solid substrate composite 100 is drawn to the cooling surface 211 and closes the openings 236 of the air ducts 235. A pressure difference builds up between the environment of the solid substrate composite 100 and the air ducts 235. The pressure difference generates a gravity-independent surface force which orthogonally acts across a contact area between the cooling surface 211 and the solid substrate composite 100. A potential bending of the solid substrate composite 100 during cooling can thus be reduced or completely avoided.

FIG. 6 further shows a phase separator 213 that separates a vaporized coolant portion from a liquid coolant portion to pass only the liquid coolant portion to the coolant feeding duct 218. For example, the phase separator 213 may separate gaseous nitrogen N₂ from liquid nitrogen N₂ to pass only liquid nitrogen N₂ to the coolant feeding duct 218.

FIG. 7 shows a cooling plate 210 with the main parts of the first plate portion 214 and the second plate portion 216 formed from a porous material or porous materials. Porosity of the main parts of the first plate portion 214 and the second plate portion 216 may be in a range from 20% to 45%. The pores form a network of continuous air ducts 235 connecting openings 236 in the cooling surface 211 with openings in a backside surface of the cooling plate 210 opposite the cooling surface 211. The vacuum pump 237 draws in air from the pores of the cooling plate 210.

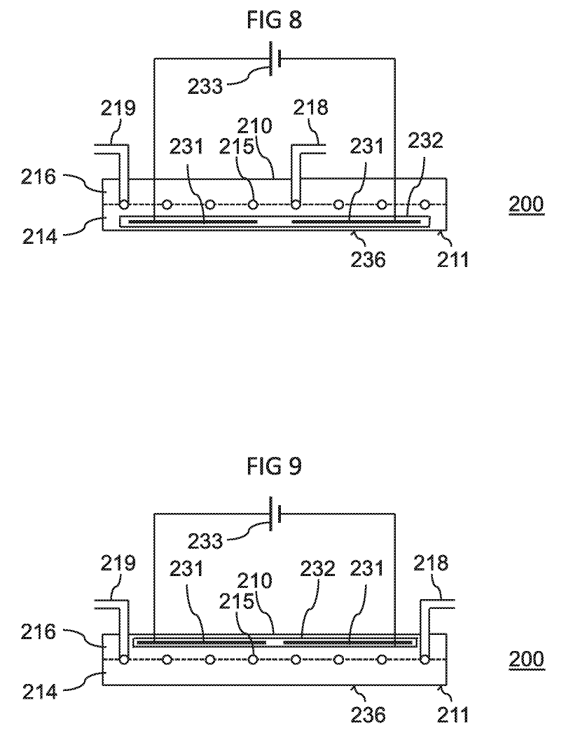

In FIG. 8 and FIG. 9, the cooling plate 210 includes two electrodes 231 and a voltage source 233. Each electrode 231 includes a plate with horizontal extensions parallel to the cooling surface 211 and a vertical extension orthogonal to the cooling surface 211. The horizontal dimensions are greater than the vertical extension by at least one order of magnitude. A dielectric embedding 232 surrounds each electrode 231 on all sides. A voltage source 233 is connected to the electrodes 231. During operation, the voltage source 233 applies a DC voltage of 100V or more between the two electrodes 231. The electrodes 231 generate an electric field with field lines crossing the cooling surface 211 approximately or perfectly orthogonally. The electric field generates an electrostatic force pressing a solid substrate composite positioned sufficiently close to the cooing surface 211 against the cooling surface 211.

In FIG. 8, the electrodes 231 are formed in the first plate portion 214 between the plane of the coolant duct 215 and the cooling surface 211. FIG. 9 shows a cooling plate 210 with the electrodes 231 formed in the second plate portion 216. The coolant duct 215 is formed between the electrodes 231 and the cooling surface 211.

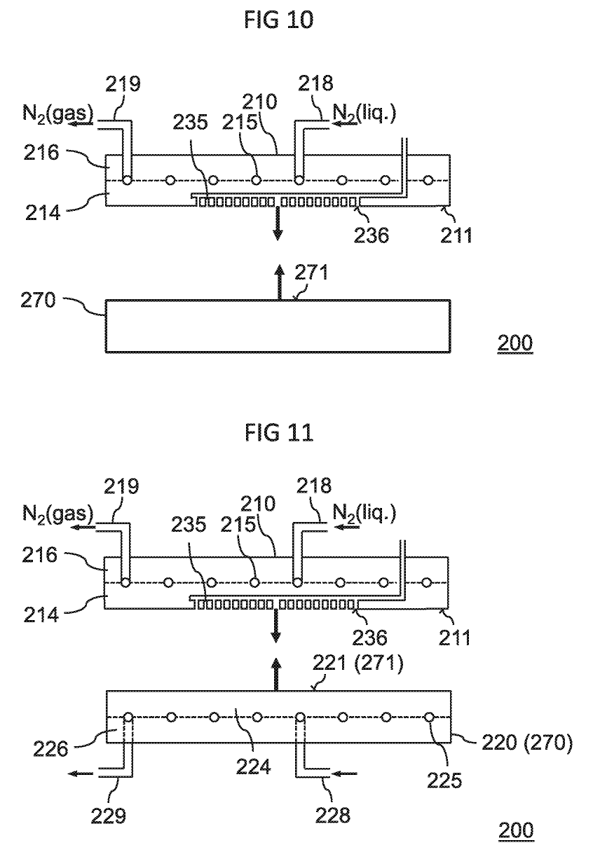

FIG. 10 and FIG. 11 show cooling plate apparatuses 200 with a cooling plate 210 in suspension configuration and further including a counter plate 270.

In FIG. 10, the counter plate 270 is configured as substrate holder with a planar working surface 271 directed upwards. The material of the counter plate 270 has a thermal conductivity that is by at least one order of magnitude lower than the thermal conductivity of the main parts of the cooling plate 210. At least one of the cooling plate 210 and the counter plate 270 is moveable along the vertical direction such that in a working configuration a solid substrate composite can be brought close to the cooling surface 211 of the cooling plate 210.

FIG. 11 shows a cooling plate apparatus 200 whose counter plate 270 is configured as auxiliary cooling plate 220. The auxiliary cooling plate 220 includes a first auxiliary plate portion 224, a second auxiliary plate portion 226, an auxiliary coolant duct 225, an auxiliary coolant feeding duct 228 and an auxiliary coolant discharge duct 229 as described above, e.g., with reference to FIG. 2C.

Though the illustrated examples show cooling plate apparatuses oriented along a direction parallel to the force of gravity, other examples may include cooling plate apparatuses oriented along a direction tilted to the force of gravity. e.g., transverse to the force of gravity.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and apparatuses including its preferred embodiments as outlined in the present document may be used stand-alone or in combination with the other methods and apparatuses disclosed in this document. In addition, the features outlined in the context of an apparatus are also applicable to a corresponding method, and vice versa. Furthermore, all aspects of the methods and apparatuses outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A method of splitting a semiconductor substrate, the method comprising:
bringing a solid substrate composite in contact with a cooling surface of a cooling plate, wherein the solid substrate composite comprises a semiconductor substrate and an auxiliary layer formed on a first surface of the semiconductor substrate, wherein the auxiliary layer and the semiconductor substrate have different coefficients of thermal expansion, wherein a release layer is formed in the semiconductor substrate between the first surface and a second surface opposite the first surface; and
cooling the cooling plate and generating a gravity-independent clamping force that clamps the solid substrate composite and the cooling plate to each other in a cooling period, wherein the solid substrate composite splits along the release layer.

2. The method of claim 1, further comprising:
applying the auxiliary layer to the semiconductor substrate to form the solid substrate composite, wherein the auxiliary layer comprises a material exhibiting a glass transition at a glass transition temperature, and wherein cooling the cooling plate cools the auxiliary layer to a temperature below the glass transition temperature.

3. The method of claim 1, further comprising:
forming the release layer in the semiconductor substrate, wherein forming the release layer comprises locally modifying a composition and/or structure of the semiconductor substrate.

4. The method of claim 1,
wherein the cooling plate is brought into direct contact with the auxiliary layer or the semiconductor substrate.

5. The method of claim 1, further comprising:
bringing the solid substrate composite in contact with a working surface of a counter plate, to position the solid substrate composite between the working surface and the cooling surface for the cooling period.

6. The method of claim 5,
wherein the counter plate is configured as an auxiliary cooling plate and the working surface of the counter plate is configured as an auxiliary cooling surface, and wherein the counter plate is cooled in the cooling period.

7. The method of claim 1,
wherein the clamping force comprises a surface force resulting from a pressure difference, wherein the pressure difference is generated by drawing air from the cooling surface.

8. The method of claim 1,
wherein the clamping force comprises an electrical force, and wherein the electrical force is generated by generating an electrical field effective between the solid substrate composite and the cooling plate.

9. The method of claim 1,
wherein cooling the cooling plate comprises:
feeding a liquid coolant into a coolant duct formed in the cooling plate, wherein the liquid coolant vaporizes in the coolant duct; and
discharging the vaporized coolant from the coolant duct.

10. The method of claim 9,
wherein a boiling temperature of the coolant is below -130 degrees Celsius.

11. A cooling plate apparatus, comprising:
a cooling plate having a cooling surface, the cooling plate being configured to cool a solid substrate composite in direct contact with the cooling surface to a temperature below -100 degree Celsius for a cooling period; and
a clamping force generation unit configured to generate a gravity-independent clamping force between the cooling plate and the solid substrate composite in direct contact with the cooling surface in the cooling period.

12. The cooling plate apparatus of claim 11,
wherein the cooling plate comprises:
a coolant feeding duct configured to receive a liquid coolant;
a coolant duct in which the liquid coolant vaporizes; and
a coolant discharge duct configured to discharge the vaporized coolant from the coolant duct.

13. The cooling plate apparatus of claim 12,
wherein the liquid coolant contains liquid nitrogen.

14. The cooling plate apparatus of claim 11, further comprising:
a phase separator configured to separate a vaporized coolant portion from a liquid coolant portion to pass only the liquid coolant portion to a coolant feeding duct of the cooling plate.

15. The cooling plate apparatus of claim 11,
wherein the cooling plate comprises a first plate portion forming the cooling surface, and wherein a thermal conductivity of a main part of the first plate portion is greater than 10 W/(m*K).

16. The cooling plate apparatus of claim 11,
wherein the clamping force generation unit comprises a plurality of air ducts formed in the cooling plate, and wherein openings of the air ducts are formed in the cooling surface.

17. The cooling plate apparatus of claim 16,
wherein the cooling plate comprises a porous material containing pores forming the air ducts.

18. The cooling plate apparatus of claim 16, further comprising:
a vacuum pump configured to draw in air from the air ducts.

19. The cooling plate apparatus of claim 11,
wherein the clamping force generation unit comprises at least one electrode configured to generate an electrical field with field lines crossing the cooling surface.

20. The cooling plate apparatus of claim 19,
wherein the cooling plate comprises a coolant duct formed along a plane parallel to the cooling surface between the at least one electrode and the cooling surface.

21. The cooling plate apparatus of claim 19, further comprising:
a voltage source configured to supply a voltage to the at least one electrode.

22. The cooling plate apparatus of claim 11, further comprising:
a counter plate comprising a working surface opposite the cooling surface of the cooling plate, wherein the cooling plate and the counter plate are configured such that a solid substrate composite can be placed between the cooling surface and the working surface.

23. The cooling plate apparatus of claim 22,
wherein the counter plate is an auxiliary cooling plate configured to be cooled before and/or in the cooling period.
